(19) United States
(12) Patent Application Publication
(10) Pub. No.: US 2015/0243925 A1
(43) Pub. Date: Aug. 27, 2015

(54) ORGANIC LIGHT-EMITTING DIODE DEVICE

(71) Applicant: InnoLux Corporation, Miao-Li County (TW)

(72) Inventors: Hao-Jung HUANG, Miao-Li County (TW); Tun-Huang LIN, Miao-Li County (TW)

(21) Appl. No.: 14/619,362

(22) Filed: Feb. 11, 2015

(30) Foreign Application Priority Data
Feb. 27, 2014 (TW) 103106708

(51) Int. Cl. H01L 51/52

(52) U.S. Cl. CPC H01L 51/5246

(57) ABSTRACT

An organic light-emitting diode device, including: a first substrate, wherein an organic light-emitting diode element is disposed on the first substrate; a second substrate, disposed to be opposite to the first substrate; a frit, disposed between the first substrate and the second substrate, having a laser pre-sintering start/end region and forming a closed space between the first substrate and the second substrate by laser sealing. At least one side of the laser pre-sintering start/end region has a gap, and the width of the gap is no bigger than 30% of the width of the frit.

### CROSS REFERENCE TO RELATED APPLICATIONS

This application claims priority of Taiwan Patent Application No. 103106708, filed on Feb. 27, 2014, the entirety of which is incorporated by reference herein.

### BACKGROUND OF THE INVENTION

1. Field of the Invention

The invention relates to frit sealing technology for organic light-emitting diode devices, and more particularly, to organic light-emitting diode devices having a frit sealing structure formed by laser pre-sintering and laser sealing.

2. Description of the Related Art

Frit sealing technology is utilized for sealing the electronic components between two substrates in a closed space to prevent the intrusion of moisture and oxygen. It mainly uses laser light to directly heat and coat a glazed frit on a substrate, such that the frit may then be melted to seal the substrate and the other substrate (back substrate) and a closed space is formed therebetween. FIG. 1 is a schematic diagram illustrating a conventional organic light-emitting diode device. The organic light-emitting diode device may comprise a first substrate 12 in which an organic light-emitting diode (OLED) element 13 is being disposed, a second substrate 10 disposed to be opposite the first substrate 12, a frit 11 disposed between the first substrate 12 and the second substrate 10 and an Thin-Film Transistor (TFT) element 14 disposed on the first substrate 12. The frit 11 is being performed with a laser sealing operation through the laser light indicated by the arrow shown in FIG. 1 to form a closed space with the first substrate 12 and the second substrate 10, and the organic light-emitting diode (OLED) element 13 and the Thin Film Transistor (TFT) element 14 are disposed on the substrate 12 in this closed space.

In conventional frit-sealing technology, first, the frit is coated on the cover of the bare glass, and the cover together with the frit are put into an oven to glaze the frit by a temperature such as high as 500° C. Then, the cover glass with the glazed frit and the substrate (disposed with the semiconductor elements thereon, e.g. an organic light emitting display element), are sealed, and the cover glass and the substrate are further sealed by laser sealing to seal the semiconductor elements in the closed space formed between the frit, the cover glass, and the substrate. However, frit sealing technology is only applied in cases where the cover glass is bare glass, and the use of the oven to glaze the frit may result in time cost heating and cooling, dealing with temperature variations, and other problems. Accordingly, in another conventional frit sealing technology, the laser light is used to heat a portion of the frit to glaze the frit by pre-sintering, thereby replacing the oven-glazing process. By doing so, not only can process tact time be saved, but it can also be applied to the sealing process for a temperature-dependent element (e.g., a color filter array, etc.) disposed on the cover glass.

FIG. 2A is a schematic diagram illustrating a conventional laser pre-sintering operation. As shown in FIG. 2A, closed frit 200 has been coated on a substrate (cover glass) 20. The laser beam starts to perform the laser pre-sintering operation on the frit 200 from the laser start/end region 210 along a direction indicated by the arrow shown in the FIG. 2A counterclockwise and finishes the performance of the laser pre-sintering operation on the frit 200 at the laser start/end region 210. FIG. 2B is a schematic diagram illustrating a conventional laser pre-sintered frit 201. FIG. 2C is a schematic diagram illustrating an enlarged view of a laser pre-sintering start/end region 220 of the laser pre-sintered frit 201 shown in FIG. 2B. The laser pre-sintering start/end region 220 of the laser pre-sintered frit 201 corresponds to the laser start/end region 210 in the laser pre-sintering operation. As shown in FIG. 2B and FIG. 2C, the laser pre-sintering start/end region 220 of the laser pre-sintered frit 201 may have a curved gap, resulting in seal failure in subsequent laser-sintering operations. Therefore, whether the frit sealing structure can be closed after the laser pre-sintering operation and the laser sealing operation is key to the sealing technology.

### BRIEF SUMMARY OF THE INVENTION

An embodiment of the invention provides an organic light-emitting diode device comprising a first substrate, a second substrate and a frit. An organic light-emitting diode element is disposed on the first substrate. The second substrate is opposite to the first substrate. The frit is located between the first substrate and the second substrate. The frit has a laser pre-sintering start/end region and forms a closed space between the first substrate and the second substrate by laser sealing. At least one side of the laser pre-sintering start/end region has a gap, and the width of the gap is no bigger than 30% of the width of the frit.

### BRIEF DESCRIPTION OF THE DRAWINGS

The invention can be more fully understood by reading the subsequent detailed description and examples with reference to the accompanying drawings, wherein:

FIG. 1 is a schematic diagram illustrating a conventional organic light-emitting diode device;

FIG. 2A is a schematic diagram illustrating a conventional laser pre-sintering operation of organic light-emitting diode device;

FIG. 2B is a schematic diagram illustrating a conventional laser pre-sintered frit;

FIG. 2C is a schematic diagram illustrating an enlarged view of a laser pre-sintering start/end region of a conventional laser pre-sintered frit;

FIG. 3 is a schematic diagram illustrating an embodiment of a laser pre-sintering operation of organic light-emitting diode device according to the invention;

FIGS. 4A-4E are schematic diagrams illustrating embodiments of masks according to the invention;

FIGS. 5A and 5B are schematic diagrams illustrating embodiments of enlarged views of a laser pre-sintering start/end region of a laser pre-sintered frit according to the invention; and

FIG. 6 is a schematic diagram illustrating another embodiment of an enlarged view of a laser pre-sintering start/end region of a laser pre-sintered frit according to the invention.

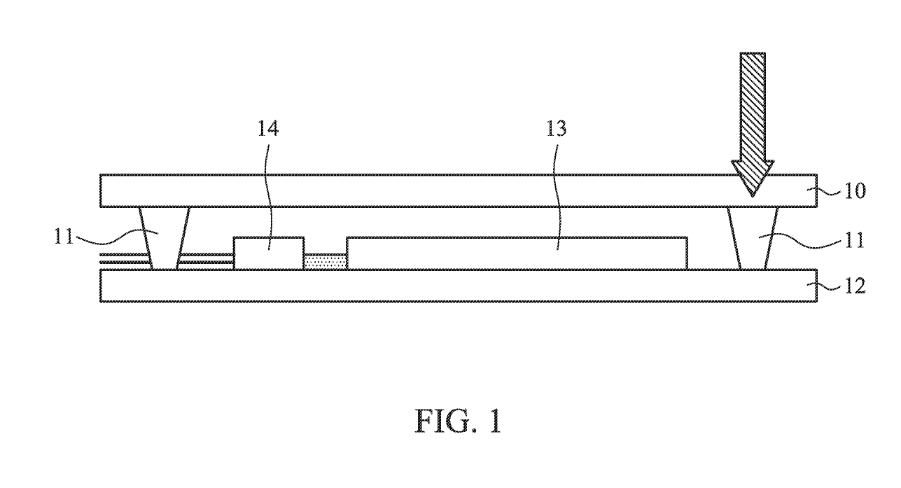

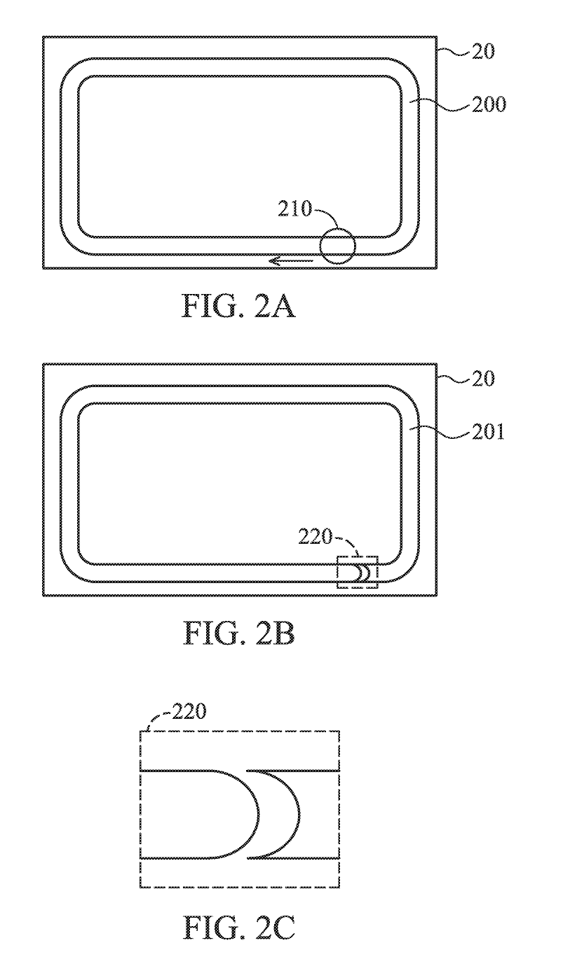

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It should be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples.

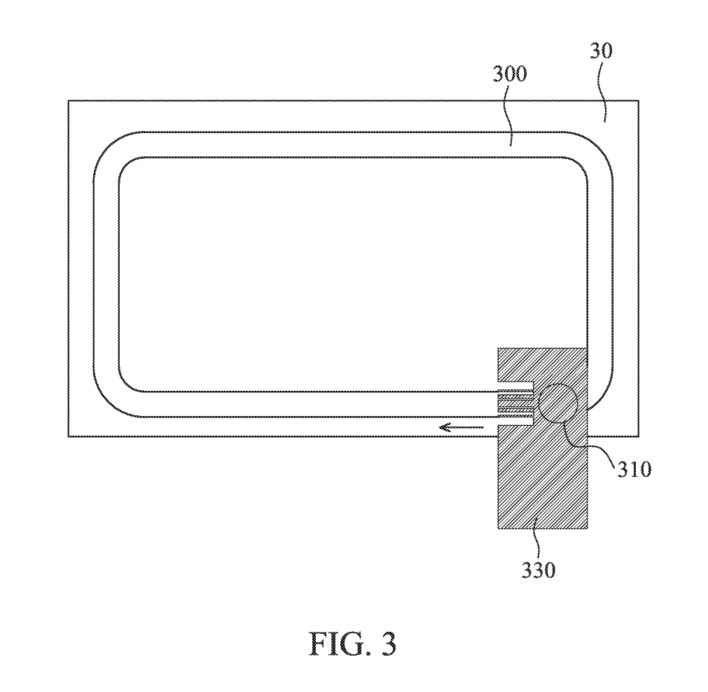

FIG. 3 is a schematic diagram illustrating an embodiment of a laser pre-sintering operation of organic light-emitting diode device according to the invention. The organic light-emitting diode device comprises a first substrate, wherein an organic light-emitting diode element is disposed on the first substrate, a second substrate which is disposed to be opposite to the first substrate, and a frit which is disposed between the first substrate and the second substrate. The frit may have a laser pre-sintering start/end region and it may form a closed space between the first substrate and the second substrate by laser pre-sintering and laser sealing, wherein the organic light-emitting diode element is disposed on the second substrate within the closed space. The pre-laser pre-sintering operation is first described in the following. As shown in FIG. 3, the frit 300 with a wall-shaped structure is coated on the substrate 30 (the first substrate), wherein the frit 300 has a height and a width. When the laser beam begins to perform the laser pre-sintering operation on the frit 300, the mask 330 is disposed above the frit 300 and the mask 330 is disposed at a predetermined distance from the frit 300 without directly contacting the frit 300, thereby preventing the frit 300 from being scratched while the mask 330 is moving. In some processes, e.g., in a process using a color filter array of the organic light-emitting diode display device, in order to ensure that the closed space between the first substrate, the second substrate and the frit is large enough, the height of the frit 300 must be above a certain height and the mask 330 must be a predetermined distance from the frit 300, such that the curved gap of the laser pre-sintering start/end region of the frit after laser pre-sintering increases, thereby reducing the sealing ratio for the subsequent laser sealing operations.

Accordingly, the embodiment of the present invention provides a mask 330 with gap compensation capability, and when the laser beam starts performing the laser pre-sintering operation on the frit 300, the mask 330 is disposed above the laser pre-sintering start/end region of the frit and disposed at a predetermined distance from the frit 300. The mask 330 includes an opaque portion and a pattern portion, for example, the comb-shaped portion of the mask 330 shown in FIG. 3 is the pattern portion, in which the pattern portion of the mask 330 may substantially deploy energy from the center of the laser beam, such that the energy that the frit 300 receives from the laser beam can be dispensed more uniformly. The transmittance of the middle portion of the frit relative to the pattern portion above is less than the transmittances of two side parts of the frit relative to the pattern portion above.

As shown in FIG. 3, the laser start/end region 310 of the laser beam corresponds to the opaque portion, so that in the laser pre-sintering operation, the laser beam may first hit the opaque portion, then move along the frit 300 and pass through the pattern portion so as to perform the laser pre-sintering operation on the frit 300 masked by the pattern portion through the pattern portion. When the laser beam is away from the pattern portion of the mask 330, the mask 330 is removed and the laser pre-sintering operation is performed on the frit 300 in the direction of the arrow shown in FIG. 3 (counterclockwise) and the laser beam is then back to the start/end region 310 of the laser beam to finish the laser pre-sintering.

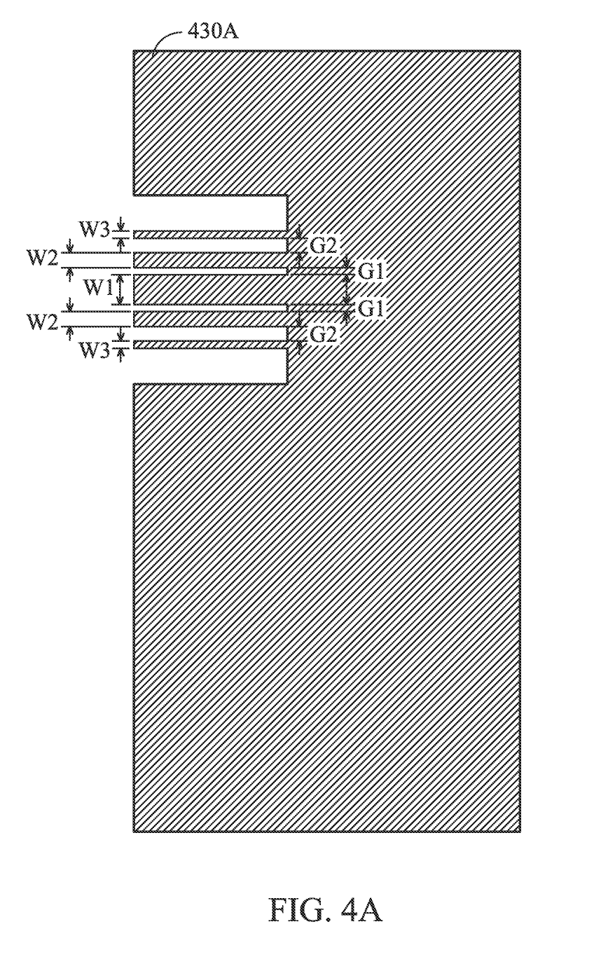

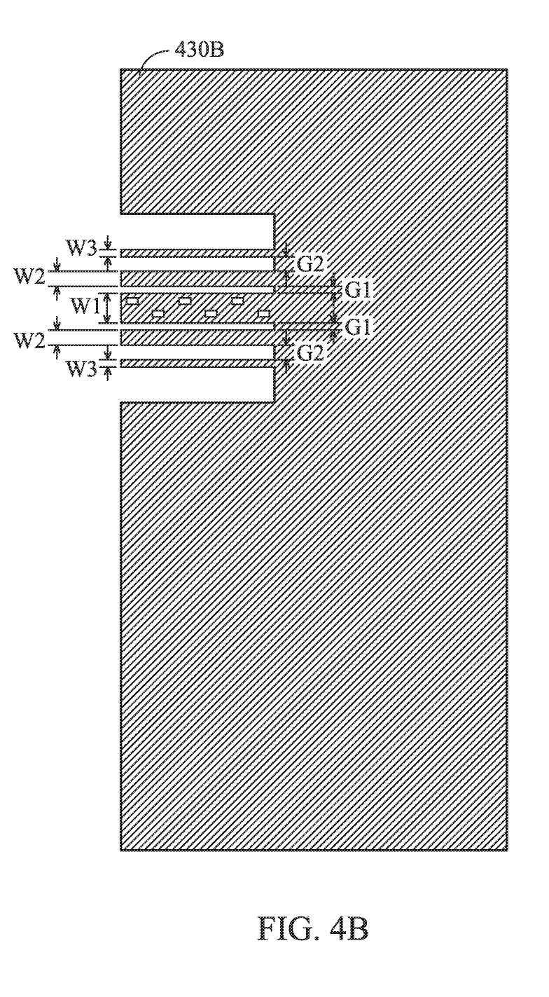

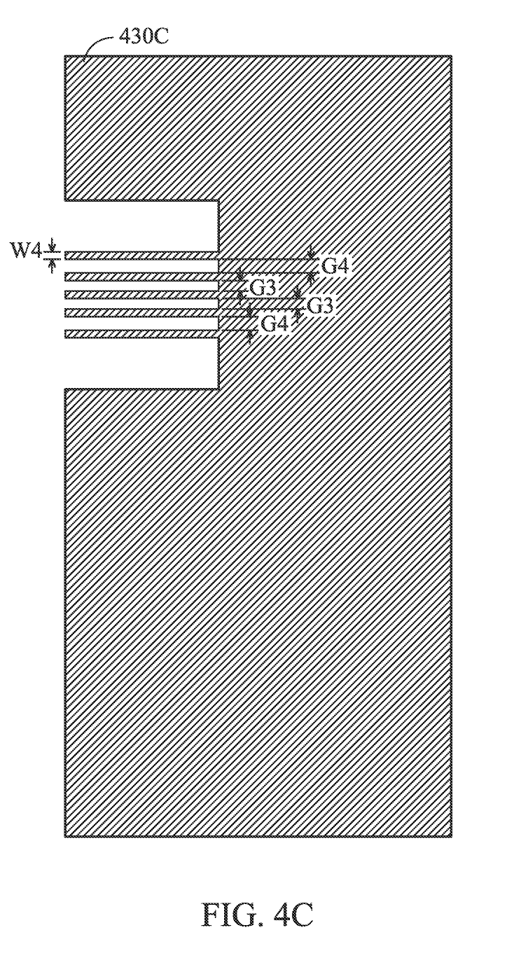

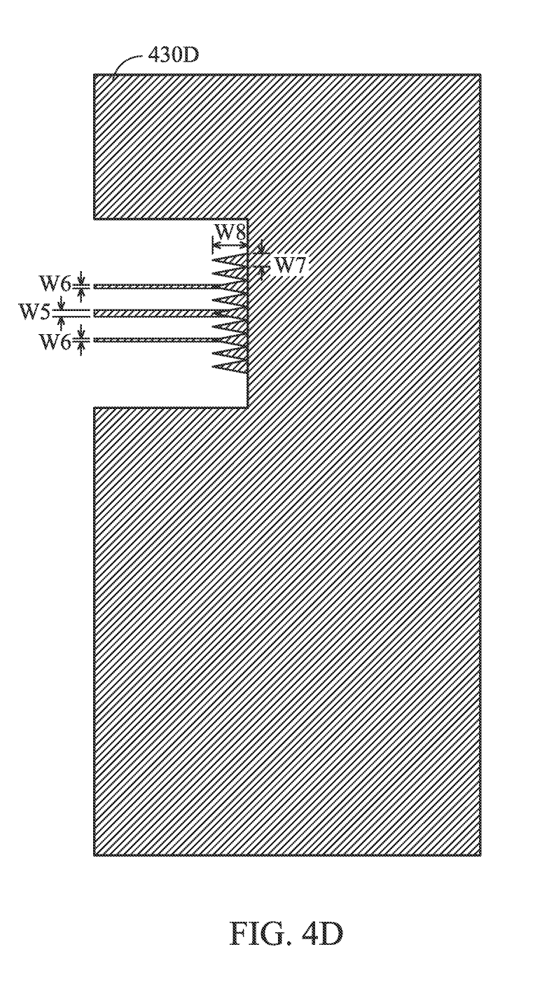

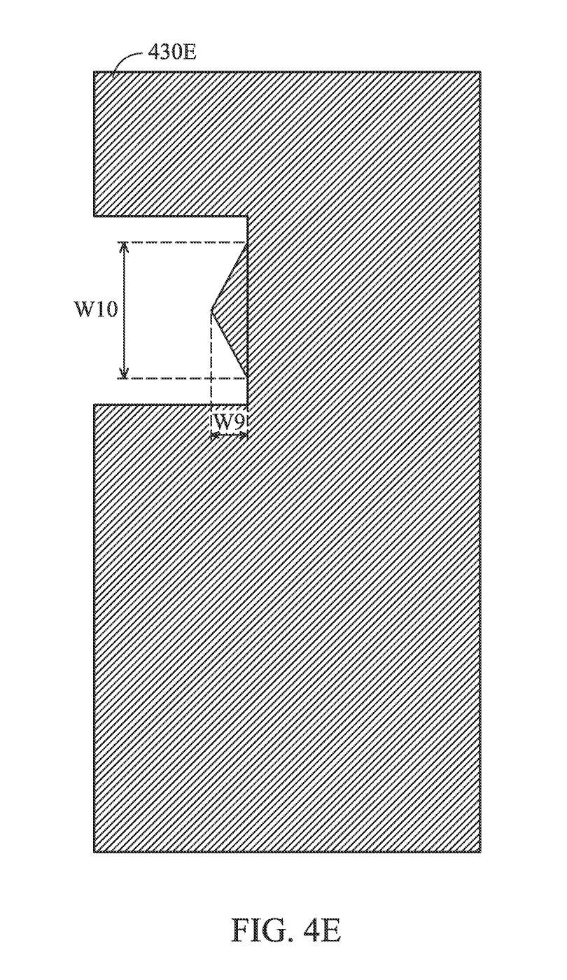

FIGS. 4A-4E are schematic diagrams illustrating embodiments of masks 430A˜430E according to the invention, wherein the mask 330 shown in FIG. 3A is the same as the mask 430 shown in FIG. 4A. In the FIGS. 4A to 4E, slash portions are opaque. Masks 430A˜430E are only different in part of the pattern portion and the pattern parts of the masks 430A˜430E essentially deploy the energy of the center of the laser beam. The pattern portions of the masks 430A˜430E can be determined according to the width of the frit, the height of the frit, the laser beam energy, the distance between the mask and the frit, and so on. The following examples illustrate the dimensions of the pattern portion of the masks 430A˜430E.

In one example, the pattern portion of the mask 430A may comprise a middle comb-shaped element, two second comb-shaped elements adjacent to the middle comb-shaped element, and two third comb-shaped elements adjacent to the second comb-shaped elements. The width W1 of the middle comb-shaped element is 100 μm, the width W2 of the second comb-shaped element is 50 μm and the width W3 of the third comb-shaped element is 25 μm. The gap width G1 between the middle comb-shaped element and the second comb-shaped element is 25 μm and the gap width G2 between the second comb-shaped element and the third comb-shaped element is 50 μm. In one example, the pattern portion of the mask 430B is similar to the pattern portion of the mask 430A except that in the mask 430B, the middle comb-shaped element of the width W1 is also disposed with six light-transmitting gaps. In one example, the pattern portion of the mask 430C includes five comb-shaped elements of the same width, the width W4 of each of the comb-shaped elements being 25 μm, the gap width G3 being 25 μm and the gap width G4 being 50 μm. In one example, the pattern portion of the mask 430D includes nine tine-shaped elements, wherein the width W7 of each tine-shaped element in a first direction is 50 μm and the width W8 of each tine-shaped element in a second direction is 150 μm. The middle tine-shaped element of the tine-shaped elements is further combined with a comb-shaped element which has a width W5 of 25 μm. The tine-shaped element that is apart from the middle tine-shaped element with a tine-shaped element is further combined with a comb-shaped element which has a width W6 equal to 15 μm. In one example, the pattern portion of the mask 430E includes an isosceles triangle element, wherein the width W10 of the isosceles triangle element in the first direction is 450 μm and the width W11 of the isosceles triangle element in the second direction is 150 μm. It should be noted that the masks 430A˜430E and the aforementioned dimension data are only used to illustrate that the pattern portion of the mask used in the laser pre-sintering substantially reduces the energy of the center of laser beam to force the transmittance of the middle portion of the frit (relative to the pattern portion) to be less than the transmittance of the two side parts of the frit (relative to the pattern portion), and the invention is not limited thereto. For example, the mask 430A may have an odd number of comb-shaped elements, e.g., 7, numbering three or more. The widths of the masks 430A˜30D in the second direction may correspond to the closed path that the frit 200 coats on the substrate 20.

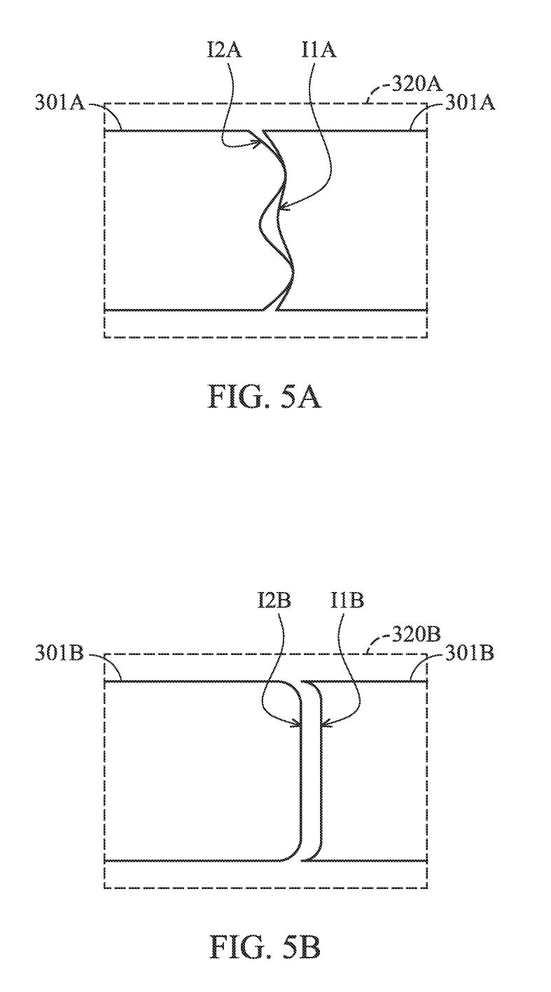

FIGS. 5A and 5B are schematic diagrams illustrating embodiments of enlarged views of laser pre-sintering start/end regions 320A and 320B of laser pre-sintered fits 301A and 301B according to the invention. By using a mask that includes an opaque portion and a pattern portion, the energy of the center of the laser beam can be substantially reduced during the laser pre-sintering operation. For example, masks 430A˜430E, the first mask interface I1A and the second interface I2A of the laser sealed frit 301A can be interfaces with multiple curvatures, as shown in FIG. 5A. Alternatively, the first mask interface I2A and the second interface I2B of the laser sealed frit 301B can be interfaces with a large curvature radius, as shown in FIG. 5B. This improves the degree of matching between the first mask interface and the second interface of the laser pre-sintering start/end regions in order to improve the curved gap of the laser pre-sintering start/end region and increase the ratio of the adhesive for laser sealing.

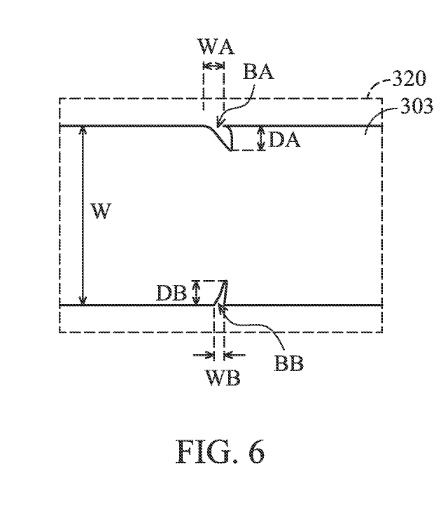

FIG. 6 is a schematic diagram illustrating another embodiment of an enlarged view of a laser pre-sintering start/end region 320 of a laser-sealed frit 303, according to the invention. The laser-sealed frit 303 uses the above-mentioned masks in the previous laser pre-sintering operation. By using the above-mentioned masks in the previous laser pre-sintering operation, the first mask interface and the second interface of the laser pre-sintering start/end region of the frit can be interfaces with multiple curvatures or interfaces with a large curvature radius, as shown in FIG. 5A and FIG. 5B, respectively.

In the laser sealing operation, the laser beam performs the laser sealing operation on the frit whose first mask interface and second interface of laser pre-sintering start/end region are interfaces with multiple curvatures or interfaces with a large curvature radius along the opposite direction of the traveling direction of the laser beam (e.g., in the direction opposite to the direction shown by the arrow in FIG. 3). As shown in FIG. 6, two sides of the laser pre-sintering start/end region 320 of the laser sealed frit 303 have a gap BA and a gap BB, wherein the widths WA and WB of the gaps BA and BB are not bigger than 30% of the width W of the frit 303 while the depths DA and DB of the gaps BA and BB are not bigger than 10% of the width W of the frit 303, thus improving the sintered ratio greatly, compared to the prior art. For example, the sintered ratio can be bigger than 80%. It should be noted that, although both sides of the laser pre-sintering start/end region of the laser sealed frit 303 have gaps in FIG. 6, but in another embodiment, the gap may only be present on one side of the laser pre-sintering start/end region of the laser sealed frit. Similarly, the width of this gap is no bigger than 30% of the width of the frit, while the depth of the gap is no bigger than 10% of the width of the frit.

In summary, the organic light-emitting diode device of the present invention comprises a first substrate, wherein an organic light-emitting diode element is disposed on the first substrate, a second substrate disposed to be opposite to the first substrate and a frit disposed between the first substrate and the second substrate. The frit has a laser pre-sintering start/end region and forms a closed space between the first substrate and the second substrate by laser sealing, wherein at least one side of the laser pre-sintering start/end region has a gap, the width of the gap is no bigger than 30% of the width of the frit and the depth of the gap is no bigger than 10% of the width of the frit. As mentioned, the sealing ratio of the frit seal structure of the present invention can be considerably improved over the prior art, thus increasing the sealing degree of the frit in the organic light-emitting diode device and further providing the organic light-emitting diode element in the closed space with better protection.

The above description is presented to enable a person of ordinary skill in the art to practice the present invention as provided in the context of a particular application and its requirements. Those with skill in the art can easily adjust it on the basis of design or purpose to implement the same and/or to achieve the same advantages of the embodiments described herein. Various modifications to the described embodiments will be apparent to those with skill in the art, and the general principles defined herein may be applied to other embodiments. Therefore, the scope of the appended claims should be accorded to the broadest interpretation so as to encompass all such modifications and similar arrangements. The method represents only illustrative and exemplary steps, and these steps are not necessarily performed in the order indicated. Those with skill in the art can add, replace, change the order of and/or eliminate steps to make adjustments as appropriate and consistent with the spirit and scope of the disclosed embodiments.

What is claimed is:

1. An organic light-emitting diode device, comprising:
a first substrate, wherein an organic light-emitting diode element is disposed on the first substrate;
a second substrate disposed to be opposite to the first substrate; and
a frit, disposed between the first substrate and the second substrate, having a laser pre-sintering start/end region and forming a closed space between the first substrate and the second substrate by laser sealing, wherein at least one side of the laser pre-sintering start/end region has a gap, and the width of the gap is no bigger than 30% of the width of the frit.

2. The organic light-emitting diode device of claim 1, wherein the depth of the gap is not bigger than 10% of the width of the frit.

3. The organic light-emitting diode device of claim 1, wherein at the beginning of performing the laser pre-sintering with the frit, a mask is disposed above the laser pre-sintering start/end region and ranged to the frit at a predetermined distance.

4. The organic light-emitting diode device of claim 3, wherein the mask further comprises an opaque portion and a pattern portion, wherein the laser pre-sintering start/end region of the laser beam corresponds to the opaque portion and the pattern portion essentially deploys the energy of the center of the laser beam.

5. The organic light-emitting diode device of claim 4, wherein in the laser pre-sintering, after the laser beam departs from the pattern portion, the mask departs from above the laser pre-sintering start/end region, so that the frit of the laser pre-sintering start/end region can be heated and glazed.

6. The organic light-emitting diode device of claim 4, wherein the laser pre-sintering start/end region prior to performing the laser sealing and subsequent to performing the laser pre-sintering includes a first interface and a second interface, and the first interface and the second interface are interfaces with multiple curvatures, or interfaces with a large curvature radius.

7. The organic light-emitting diode device of claim 4, wherein in the laser pre-sintering, the laser beam travels along the frit through the pattern portion.

8. The organic light-emitting diode device of claim 4, wherein the pattern portion comprises an odd number of comb-shaped opaque components numbering three or more.

9. The organic light-emitting diode device of claim 8, wherein the comb-shaped opaque components have equal widths and the comb-shaped opaque component that is far away from the middle one of the comb-shaped opaque components has a larger gap between the adjacent comb-shaped opaque components in the direction toward the middle comb-shaped opaque component.

10. The organic light-emitting diode device of claim 1, wherein the transmittance of the middle portion of the frit relative to the pattern portion above is less than the transmittance of the two side parts of the frit relative to the pattern portion above.
